(19) United States
(12) Patent Application Publication
(10) Pub. No.: US 2026/0362874 A1
(43) Pub. Date: Nov. 12, 2026

(54) LIGHT-EMITTING DIODE AND TURBIDITY SENSOR COMPRISING SUCH A LIGHT-EMITTING DIODE

(71) Applicant: IFM ELECTRONIC GMBH, Essen (DE)

(72) Inventors: Philip Johannes EGGER, Tettnang (DE); Patrick HAMBERGER, Weingarten (DE)

(73) Assignee: IFM ELECTRONIC GMBH, Essen (DE)

(21) Appl. No.: 19/135,182

(22) PCT Filed: Dec. 8, 2023
(86) PCT No.: PCT/EP2023/084848

§ 371 Date: Jun. 3, 2025

(30) Foreign Application Priority Data
Dec. 9, 2022 (DE) 102022132786.8

(51) Int. Cl. H10H 29/20; G01N 21/85; H10F 30/22; H10F 39/90; H10F 77/40; H10F 77/50; H10H 20/85; H10H 20/856

(52) U.S. Cl. CPC H10H 29/20; G01N 21/8507; H10F 30/22; H10F 39/90; H10F 77/407; H10F 77/50; H10H 20/8506; H10H 20/856

(57) ABSTRACT

A light-emitting diode (LED), in particular for a turbidity sensor, includes an LED chip as a radiation emitter, wherein the LED chip is hermetically enclosed by a base, a housing and a converging lens, wherein a photodiode as a radiation receiver is arranged next to the LED chip and as a reference receiver detects the radiation intensity of the LED chip, wherein the LED chip and the photodiode are enclosed by a stop element, which has a through-hole for forwarding beams emitted by the LED chip into the surroundings, but for the rest forms a reflection plane that causes the beams from the LED chip to pass to the photodiode and at the same time limits the intrusion of stray light from the surroundings. In addition, a turbidity sensor includes such a light-emitting diode.

The invention relates to a light-emitting diode and a turbidity sensor comprising such a light-emitting diode.

A light-emitting diode, or LED for short, is generally defined as a semiconductor component that emits light when an electrical current flows in the forward direction. It substantially comprises a semiconductor crystal which forms the actual radiation emitter in the form of an LED chip and is usually arranged on a carrier plate. The LED chip is electrically connected via bonding wires. This arrangement is encased in a light-bundling transparent housing or a sleeve with a separate converging lens.

Turbidity sensors are provided to analyze a medium, in particular a liquid, with regard to the optical properties. The focus is on determining the proportion of suspended matter. A light source, typically a light-emitting diode, emits light, in particular infrared light, through the medium to a radiation receiver. Suspended matter in the medium attenuates the light due to stray light and absorption so that the radiation intensity received by the radiation receiver is a measure of the turbidity of the medium.

The light source is naturally subject to a certain aging effect. In order to ensure that a reduced radiation intensity arriving at the radiation receiver is caused exclusively by the turbidity properties of the medium and is not also the result of an aging effect, it is known from the prior art, for example from DE 10 2012 007 864 A1, to arrange an additional radiation receiver within the turbidity sensor next to the light source. This additional radiation receiver then serves as a reference receiver in that it detects the radiation intensity of the light source largely unaffected by the medium. Often, a slight influence by the medium cannot be completely ruled out, but this is then of no further significance for the measurement.

The problem is that the reference receiver can also be subject to stray light influences which would then reduce its informative value regarding the aging effects of the light source. Furthermore, the additional component inevitably increases the space requirement.

The object of the invention is to monitor the radiation intensity of the light source using a reference receiver in a very compact and space-saving manner and to largely protect it from stray light influences.

The object is achieved according to the invention by a light-emitting diode having the features of claim 1 and by a turbidity sensor having the features of claim 2. Advantageous embodiments of the invention are specified in the dependent claims.

First, the LED comprises an LED chip as a radiation emitter which is hermetically enclosed by a base, a housing and a converging lens. According to the invention, a photodiode as a radiation receiver is arranged next to the LED chip and, as a reference receiver, detects the radiation intensity of the LED chip. Both the LED chip and the photodiode are enclosed by a stop element which has a through-hole for forwarding the beams emitted by the LED chip into the surroundings, but otherwise forms a reflection plane, by means of which the beams from the LED chip pass to the photodiode and at the same time limits the intrusion of stray light from the surroundings.

The core of the invention is therefore to arrange the reference receiver within the light source, i.e. the light-emitting diode, and to thereby achieve a very compact and extremely space-saving design. At the same time, the stop element limits the intrusion of stray light from the medium so that it is ensured that the reference receiver substantially only receives radiation from the radiation emitter and accordingly enables reliable information about the current radiation intensity of the radiation emitter and any aging effects of the radiation emitter. In addition, such a structure is also hermetically sealed so that moisture which can arise, for example, through condensation, has no effect on the LED chip, the reference receiver or the other components within the LED.

A second aspect relates to a turbidity sensor in which the light source or the radiation emitter unit is designed as such a light-emitting diode according to the invention.

Advantageously, the reference receiver is designed as a photodiode. The stop element is preferably made of a ceramic material.

The invention is explained in more detail below using embodiments with reference to the drawings, in which schematically:

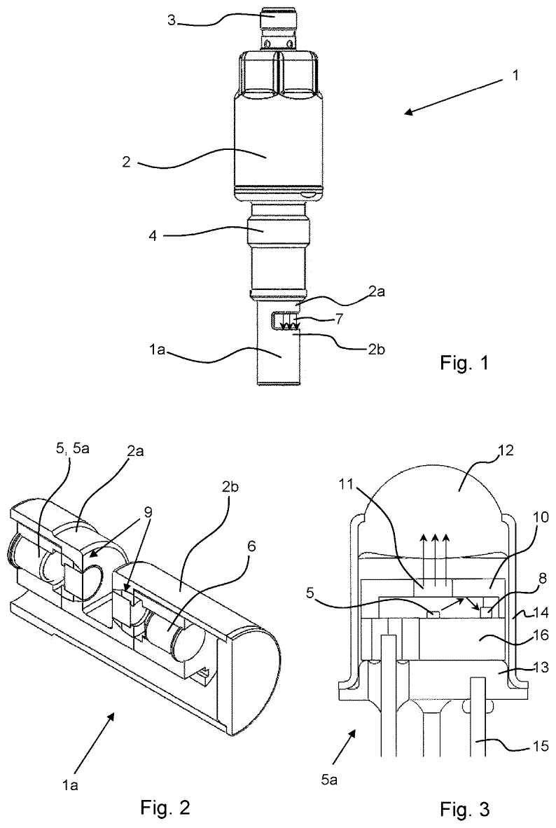

FIG. 1 shows a turbidity sensor according to the invention;

FIG. 2 shows a sectional view of a sensor tip of the turbidity sensor according to the invention, and

FIG. 3 shows a sectional view of a light-emitting diode according to the invention.

In the following description of the preferred embodiments, the same reference signs denote the same or comparable components.

FIG. 1 shows a turbidity sensor 1 according to the invention in a side view from the outside. The sensor 1 comprises a housing 2. Part of the housing 2 is a process connection 2 in the form of an external thread with which the sensor 1 is connected to a container containing the medium to be measured, i.e. a pipeline, a tank or similar. This connection is usually made by means of a flange molded onto the container or a corresponding adapter. The housing or sensor tip 1a correspondingly protrudes into the container and thus into the medium. The sensor tip 1a has a slot-like recess in the region of two housing portions 2a, 2b, which represents the actual measuring environment. The medium to be measured is then located in this recess and thus in the beam path 7 between a radiation emitter unit 5a or light source located in the first housing portion 2a, which is designed as a light-emitting diode with an LED chip 5, and a radiation receiver unit with a radiation receiver 6 located in the second housing portion 2b.

The turbidity sensor is shown here as a so-called transmitter device which has no display or operating unit and merely outputs an analog voltage or current signal that corresponds to the measurement result via a plug connection 3 and which is made available to a higher-level control unit, e.g. a PLC, for further processing and evaluation.

FIG. 2 shows a sectional view of the sensor tip 1a of the turbidity sensor 1 according to the invention. In the housing portions 2a, 2b, in the radiation direction in the region behind the light-emitting diode 5a and in the radiation direction in the region in front of the radiation receiver 6, a window region 9 is arranged through which the beam path 7 runs. The radiation intensity received by the radiation receiver 6 can then be evaluated as a measure of the turbidity of the medium.

FIG. 3 shows a sectional view of a light-emitting diode 5a according to the invention as a radiation emitter unit. The light-emitting diode 5a substantially consists of a base 13, a sleeve 14 located thereon and a converging lens 12 opposite the base 13 and closing the sleeve 14. Various electrical connection pins 15 are routed through the base 13 and contact a circuit board 16. The LED chip 5 as the actual radiation emitter and the reference receiver 8 designed as a photodiode are inter alia arranged on the circuit board 16.

The circuit board 16 and thus also the LED chip 5 as well as the reference receiver 8 are covered by a stop element 10. This stop element 10 has a through-hole 11 through which the rays emitted by the radiation emitter 5 are passed in the direction of the converging lens 12 and thus in the direction of the medium. The radiation direction is indicated schematically by the three parallel arrows.

The reference receiver 8, on the other hand, is arranged between the stop element 10 and the circuit board 16 in such a way that the influence of stray light from the medium is virtually eliminated, and the stop element 10 substantially forms a reflection plane through which the rays from the LED chip 5 reach the reference receiver 8. The reflected radiation is also schematically represented by two arrows. In this way it can be ensured that the reference receiver 8 substantially only receives the radiation from the LED chip 5, and thereby allows reliable information about the current radiation intensity of the LED chip 5 or any aging effects of the LED chip 5. At the same time, this design feature does not result in any significant enlargement of the entire light-emitting diode 5a as a component so that a compact design is still possible. However, since the use of this LED in a turbidity sensor 1 eliminates the need for an externally arranged reference receiver of sorts, the turbidity sensor 1 itself can be designed in a very compact and space-saving manner.

### LIST OF REFERENCE SIGNS

1 Turbidity sensor
1a Sensor tip
2 Housing
2a Housing portion
2b Housing portion
3 Plug connection
4 Process connection
5 LED chip, radiation emitter
5a Radiation emitter unit, light source
6 Radiation receiver
7 Beam path
8 Reference receiver
9 Window region
10 Stop element
11 Through-hole
12 Converging lens
13 Base
14 Sleeve
15 Electrical connections
16 Circuit board

1. A light-emitting diode (LED), comprising:
an LED chip as a radiation emitter,
wherein the LED chip is hermetically enclosed by a base, a housing and a converging lens,
wherein a photodiode operates as a radiation receiver arranged next to the LED chip and operates as a reference receiver to detect a radiation intensity of the LED chip, and
wherein the LED chip and the photodiode are enclosed by a stop element which has a through-hole for forwarding the beams emitted by the LED chip into the surroundings, but for the rest forms a reflection plane that causes the beams from the LED chip to pass to the photodiode and at the same time limits the-intrusion of stray light from the surroundings.

2. The light-emitting diode according to claim 1,
wherein the stop element is made of a ceramic material.

3. A turbidity sensor, comprising:
a radiation emitter unit; and
a radiation receiver unit, wherein the radiation emitter unit and the radiation receiver unit are arranged relative to one another in such a way that the radiation emitter unit and the radiation receiver unit form a beam path for measuring a turbidity of a medium located in the beam path, and a radiation intensity received by the radiation receiver unit is a measure of the turbidity of the medium,
wherein the radiation emitter unit including the light-emitting diode according to claim 1.

4. The turbidity sensor according to claim 3,
wherein the radiation receiver operates as a photodiode.
